(19) United States
(12) Patent Application Publication
(10) Pub. No.: US 2026/0013040 A1
(43) Pub. Date: Jan. 8, 2026

(54) CIRCUIT BOARD AND METHOD FOR FABRICATING THE SAME

(71) Applicant: Unimicron Technology Corp., Taoyuan City (TW)

(72) Inventors: Chia-Lin CHUANG, Taoyuan City (TW); Yu-Cheng LIN, Taoyuan City (TW); Cheng-Lin YANG, Taoyuan City (TW); Yu-Cheng HUANG, Taoyuan City (TW)

(21) Appl. No.: 18/830,601

(22) Filed: Sep. 11, 2024

(30) Foreign Application Priority Data
Jul. 2, 2024 (TW) 113124727

(51) Int. Cl. H05K 1/02; H05K 3/46

(52) U.S. Cl. CPC H05K 1/0298; H05K 3/4644

(57) ABSTRACT

A circuit board and a method for fabricating the circuit board are provided. The circuit board includes a first insulation layer, a circuit layer, a second insulation layer and at least one conductive structure. The circuit layer is embedded in the first insulation layer, and the second insulation layer is disposed on the first insulation layer. The conductive structure has a first surface and a second surface opposite to each other, and the conductive structure is embedded in the second insulation layer. A flat surface of the second insulation layer exposes the second surface of the conductive structure, and the second surface is recessed to the flat surface of the second insulation layer. The conductive structure includes the metal layer and the diffusion barrier layer. The diffusion barrier layer is disposed between the metal layer and the second insulation layer and surrounds the outer surface of the metal layer.

This application claims priority to Taiwan Application Serial Number 113124727, filed July 02, 2024, which is herein incorporated by reference in its entirety.

### BACKGROUND

### TECHNICAL FIELD

The present disclosure relates to a circuit board and the method for fabrication of the same.

### DESCRIPTION OF RELATED ART

As the tendency for developing thinner and lighter electronic communication products, the demand for circuit density in circuit boards is increasing, so that the pitch between the circuits is getting shorter. When the pitch between the circuits is between 1 µm and 2 µm, the copper atoms of one circuit are prone to diffusing to the adjacent circuits. Thus, the leakage current in the circuit board increases significantly, so that the reliability of the circuit board decreases. In order to prevent the copper atoms from diffusing to the adjacent circuits, the diffusion barrier layer should be disposed on the outer layer of the circuit.

Recently, the conductive vias which are similar to dual damascene structures are used to increase circuit density, while the surfaces of the circuit boards with the dual damascene structure should be flattened by planarization processes. In general, the planarization processes include the chemical-mechanical polishing (CMP). Since the cost of CMP is relatively high, it is difficult to reduce the manufacturing cost of circuit boards.

### SUMMARY

Accordingly, the disclosure is to provide a circuit board which is advantage for reducing the manufacturing cost when the pitch between the circuit layers is shortened.

At least one embodiment of the disclosure provides a method for fabrication of the aforementioned circuit board.

At least one embodiment of the disclosure provides a circuit board including a first insulation layer, a circuit layer, a second insulation layer and at least one conductive structure. The circuit layer is embedded in the first insulation layer, and the second insulation layer is disposed on the first insulation layer. The at least one conductive structure is embedded in the second insulation layer and has a first surface and a second surface opposite to each other. A flat surface of the second insulation layer exposes the second surface of the at least one conductive structure, and the second surface is recessed to the flat surface of the second insulation layer. The at least one conductive structure includes a metal layer and a diffusion barrier layer. The diffusion barrier layer is disposed between the metal layer and the second insulation layer and surrounds an outer surface of the metal layer.

At least in one embodiment of the disclosure, the circuit board includes a plurality of conductive structures, and at least one of the conductive structures is disposed on the circuit layer and electrically connected to the circuit layer, and the first surface of the at least one of the conductive structures touches the circuit layer directly.

At least in one embodiment of the disclosure, the first surface of another one of the conductive structures is spaced from the circuit layer.

At least in one embodiment of the disclosure, the second surface of the at least one conductive structure includes a first end surface of the metal layer and a second end surface of the diffusion barrier layer, and the second end surface of the diffusion barrier layer is recessed to the first end surface of the metal layer.

At least in one embodiment of the disclosure, the at least one conductive structure further includes an adhesive layer distributed between the metal layer and the diffusion barrier layer. The second surface of the at least one conductive structure further comprises a third end surface of the adhesive layer, and the third end surface of the adhesive layer is recessed to the first end surface of the metal layer.

At least in one embodiment of the disclosure, the second end surface of the diffusion barrier layer is recessed to the third end surface of the adhesive layer.

At least in one embodiment of the disclosure, a first spacing is located between the second end surface of the diffusion barrier layer and the third end surface of the adhesive layer, and the first spacing is between 1 nm and 100 nm. A second spacing is located between the third end surface of the adhesive layer and the first end surface of the metal layer, and the second spacing is between 10 nm and 200 nm.

At least in one embodiment of the disclosure, the circuit board further includes an etch stop layer disposed between the first insulation layer and the second insulation layer. The etch stop layer covers the circuit layer and exposes an interface of the circuit layer where the at least one conductive structure is disposed.

At least in one embodiment of the disclosure, the circuit board further includes an etch stop layer disposed on the second insulation layer and covering the second surface of the at least one conductive structure.

At least one embodiment of the disclosure provides a method for fabricating a circuit board. The method includes providing a substrate that includes a first insulation layer, a circuit layer embedded in the first insulation layer and a second insulation layer disposed on the first insulation layer. The second insulation layer includes a flat surface, and this flat surface and the circuit layer are located at two opposite sides of the second insulation layer separately. The method includes removing a part of the second insulation layer to form at least one opening on the second insulation layer, and the opening exposes a first surface of the circuit layer. The method includes disposing a diffusion barrier layer on the second insulation layer and an inner wall of the opening, and the diffusion barrier layer covers the first surface of the circuit layer. The method includes disposing a metal material on the diffusion barrier layer, and the metal material is located inside the opening. The method includes removing a part of the metal material to form a metal layer inside the opening, and the metal layer is electrically connected to the circuit layer. The metal layer has a first end surface that is farther away from the circuit layer, and the first end surface is recessed to the flat surface of the second insulation layer.

At least in one embodiment of the disclosure, the method further includes removing a part of the diffusion barrier layer after the metal layer is formed, so that a second end surface of the diffusion barrier layer is recessed to the first end surface of the metal layer.

At least in one embodiment of the disclosure, the method further includes disposing an etch stop layer on the second insulation layer after the part of the diffusion barrier layer is removed, and the etch stop layer covers the first end surface of the metal layer and the second end surface of the diffusion barrier layer.

At least in one embodiment of the disclosure, the method further includes disposing an adhesive layer on the diffusion barrier layer before the metal material is disposed on the diffusion barrier layer, and the adhesive layer is located inside the opening and distributed between the diffusion barrier layer and the metal layer. The method further includes removing a part of the adhesive layer after the metal layer is formed, so that a third end surface of the adhesive layer is recessed to the first end surface of the metal layer.

At least in one embodiment of the disclosure, the method of removing the part of the metal material includes wet etching.

At least in one embodiment of the disclosure, the second end surface of the diffusion barrier layer protrudes from the third end surface of the adhesive layer.

According to the aforementioned embodiments, the conductive structure (including the metal layer and the diffusion barrier layer) may be formed by wet etching. As a result, the surface of the conductive structure is recessed to the surface of the insulation layer. The process of CMP is bypassed in the fabrication of this circuit board, thereby reducing the manufacturing cost of the circuit board.

### BRIEF DESCRIPTION OF THE DRAWINGS

To illustrate more clearly the aforementioned and the other objects, features, merits, and embodiments of the present disclosure, the description of the accompanying figures are as follows:

FIG. 1A illustrates a locally cross-sectional view of a circuit board in accordance with at least one embodiment of the present disclosure.

FIG. 1B illustrates a locally cross-sectional view of a circuit board in accordance with another embodiment of the present disclosure.

FIG. 2A to FIG. 2F illustrate locally cross-sectional views of intermediate processes for fabricating the circuit board in FIG. 1A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. In addition, the number or range of numbers encompasses a reasonable range including the number described, such as within +/–30%, +/–20%, +/–10% or +/–5% of the number described, based on known manufacturing tolerances associated with manufacturing a feature having a characteristic associated with the number. The words of deviations such as “about,” “approximate,” “substantially,” and the like are chosen in accordance with the optical properties, etching properties, mechanical properties or other properties. The words of deviations used in the optical properties, etching properties, mechanical properties or other properties are not chosen with a single standard.

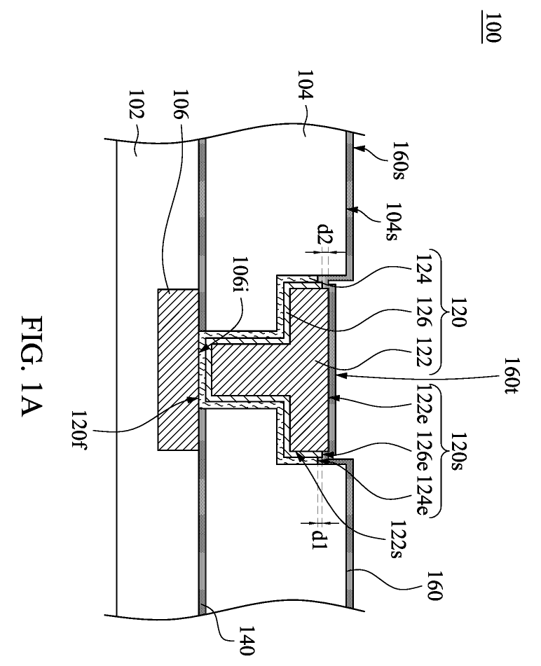

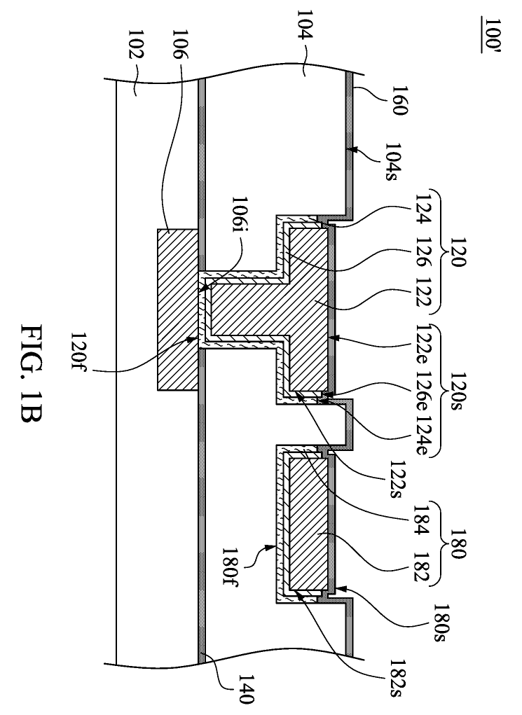

Referring to FIG. 1A, a circuit board 100 includes an insulation layer 102, an insulation layer 104, a circuit layer 106 and a conductive structure 120. The circuit layer 106 is embedded in the insulation layer 102, and the insulation layer 104 is disposed on the insulation layer 102. The materials of the insulation layer 102 and the insulation layer 104 may include insulation materials, such as organic resins (e.g., epoxy) or other similar materials, while the material of the circuit layer 106 may include conductive materials, such as copper or other similar materials.

In the embodiment, the circuit board 100 further includes an etch stop layer 140 which is disposed between the insulation layer 102 and the insulation layer 104. The etch stop layer 140 covers the circuit layer 106 and exposes an interface 106i of the circuit layer 106. In addition, the conductive structure 120 is embedded in the insulation layer 104 and is located at the circuit layer 106. The conductive structure 120 has a surface 120f and a surface 120s opposite to each other, while the surface 120f directly touches the circuit layer 106.

Since the conductive structure 120 is located at the interface 106i of the circuit layer 106, the surface 120f of the conductive structure 120 directly touches the interface 106i of the circuit layer 106. Thus, the conductive structure 120 is electrically connected to the circuit layer 106. Furthermore, a flat surface 104s of the insulation layer 104 exposes the surface 120s of the conductive structure 120, and the surface 120s is recessed to the flat surface 104s of the insulation layer 104.

In addition, the conductive structure 120 further includes a metal layer 122 and a diffusion barrier layer 124. The diffusion barrier layer 124 is disposed between the metal layer 122 and the insulation layer 104 and surrounds an outer surface 122s of the metal layer 122. In various embodiments of the disclosure, the material of the diffusion barrier layer 124 may include titanium nitride (TiN), tantalum nitride (TaN), titanium silicon nitride (TiSiN), tungsten nitride (WN), tungsten carbide nitride (WCN), aluminum nitride (AlN), zirconium nitride (ZrN), chromium nitride (CrN) or other similar materials.

When the outer surface 122s of the metal layer 122 is encapsulated and surrounded by the diffusion barrier layer 124, the metal layer 122 is insulated from the insulation layer 104. That is, there is no direct connection between the metal layer 122 and the insulation layer 104. As a result, the probability for the material of the metal layer 122 (e.g., copper) to diffuse to the insulation layer 104 and extend to other conductive structures (e.g., the conductive vias or circuit layers of the circuit board 100) may decline. It is worth mentioning, the thickness (not denoted) of the diffusion barrier layer 124 is between 1 nm and 100 nm. Since the thickness within this range is less affective to the electrical connection, and some materials that the diffusion barrier layer 124 consists of are conductive, such as titanium nitride and tantalum nitride, the metal layer 122 may be electrically connected to the circuit layer 106.

In the embodiment, the surface 120s of the conductive structure 120 includes an end surface 124e of the diffusion barrier layer 124 and an end surface 122e of the metal layer 122, while the end surface 124e of the diffusion barrier layer 124 is recessed to the end surface 122e of the metal layer 122. Furthermore, in some embodiments, the conductive structure 120 may further include an adhesive layer 126. The adhesive layer 126 is distributed between the metal layer 122 and the diffusion barrier layer 124, and the material of the adhesive layer 126 may include such as titanium, tantalum or other similar materials. Moreover, the thickness of the adhesive layer 126 may be between 10 nm and 200 nm.

The surface 120s of the conductive structure 120 further includes an end surface 126e of the adhesive layer 126, and the end surface 126e of the adhesive layer 126 is recessed to the end surface 122e of the metal layer 122. In the embodiment, the end surface 124e of the diffusion barrier layer 124 may be recessed to the end surface 126e of the adhesive layer 126. Thus, the altitude difference among the end surface 122e of the metal layer 122, the end surface 126e of the adhesive layer 126 and the end surface 124e of the diffusion barrier layer 124 is vertically stepped in the cross-sectional view of FIG. 1A. It is worth mentioning, the vertically stepped altitude difference is not visible to naked eyes but electron microscopies, such as transmission electron microscopies (TEMs).

However, the altitude difference between the end surface 124e of the diffusion barrier layer 124 and the end surface 126e of the adhesive layer 126 is not limited to the embodiment. In other embodiments, the end surface 124e of the diffusion barrier layer 124 may protrude from the end surface 126e of the adhesive layer 126. Further, the end surface 124e of the diffusion barrier layer 124 may be flush with the end surface 126e of the adhesive layer 126.

It is worth mentioning, in some embodiments, a spacing d1 is located between the end surface 124e of the diffusion barrier layer 124 and the end surface 126e of the adhesive layer 126, while the spacing d1 is between 1 nm and 100 nm. In addition, a spacing d2 is located between the end surface 126e of the adhesive layer 126 and the end surface 122e of the metal layer 122, while the spacing d2 is between 10 nm and 200 nm.

In the embodiment, the circuit board 100 further includes an etch stop layer 160. The etch stop layer 160 is disposed on the insulation layer 104 and covers the surface 120s of the conductive structure 120. As shown in FIG. 1A, the etch stop layer 160 is adhered to the surface 120s of the conductive structure 120. When the etch stop layer 160 has a consistent thickness, a surface 160s of the etch stop layer 160 extends along with the end surface 122e of the metal layer 122, the end surface 126e of the adhesive layer 126 and the end surface 124e of the diffusion barrier layer 124 and forms a stepped layer. Furthermore, the etch stop layer 160 over the conductive structure 120 may be recessed to the etch stop layer 160 over the flat surface 104s, so as to form a recessed region 160t.

It is worth mentioning, the materials of the etch stop layer 140 and the etch stop layer 160 may include silicon nitride (SiN), silicon carbonitride (SiCN), silicon oxynitride (SiON), silicon oxycarbonitride (SiOCN) or other similar materials. Further, the thicknesses of the etch stop layer 140 and the etch stop layer 160 are between 10 nm and 300 nm.

In some embodiments, the circuit board 100 may further include a circuit substrate that covers the etch stop layer 160, while this circuit substrate is not illustrated in figures. The circuit substrate covers the insulation layer 104 and the conductive structure 120 and may fill up the recessed region 160t of the etch stop layer 160, so that the surface of the circuit board 100 (i.e., the surface on one side of the circuit substrate) is flat.

Referring to FIG. 1B, in another embodiment of the disclosure, the circuit board 100’ further includes another conductive structure 180. The conductive structure 180 is similar to the conductive structure 120, that is, the conductive structure 180 also has a surface 180f and a surface 180s opposite to each other. In addition, the flat surface 104s of the insulation layer 104 also exposes the surface 180s of the conductive structure 180, while the surface 180s is recessed to the flat surface 104s of the insulation layer 104. However, the difference between the conductive structure 120 and the conductive structure 180 is that the surface 180s of the conductive structure 180 is spaced from the circuit layer 106. That is, the conductive structure 180 is not electrically connected to the circuit layer 106 directly. In other words, the conductive structure 120 and the conductive structure 180 may be a via and a trace of the circuit board 100’, respectively.

Specifically, the conductive structure 180 includes a metal layer 182 and a diffusion barrier layer 184. The diffusion barrier layer 184 is disposed between the metal layer 182 and the insulation layer 104 and surrounds an outer surface 182s of the metal layer 182. The disclosure is not limited to aforementioned embodiment which has only the conductive structure 120 and which has both of the conductive structure 120 and the conductive structure 180. In some embodiments, the circuit board may have only the conductive structure 180.

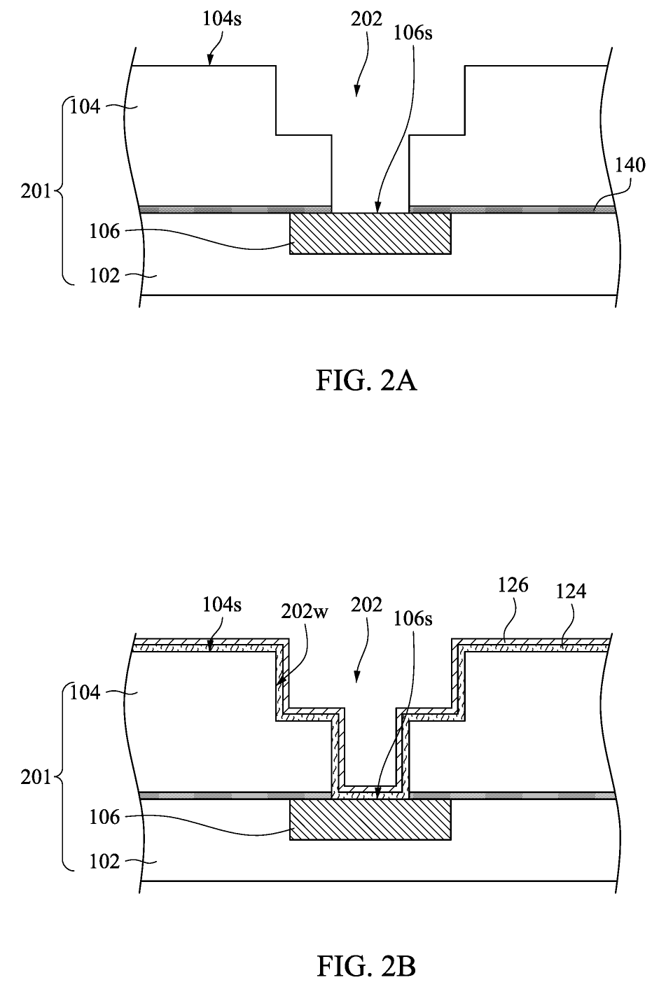

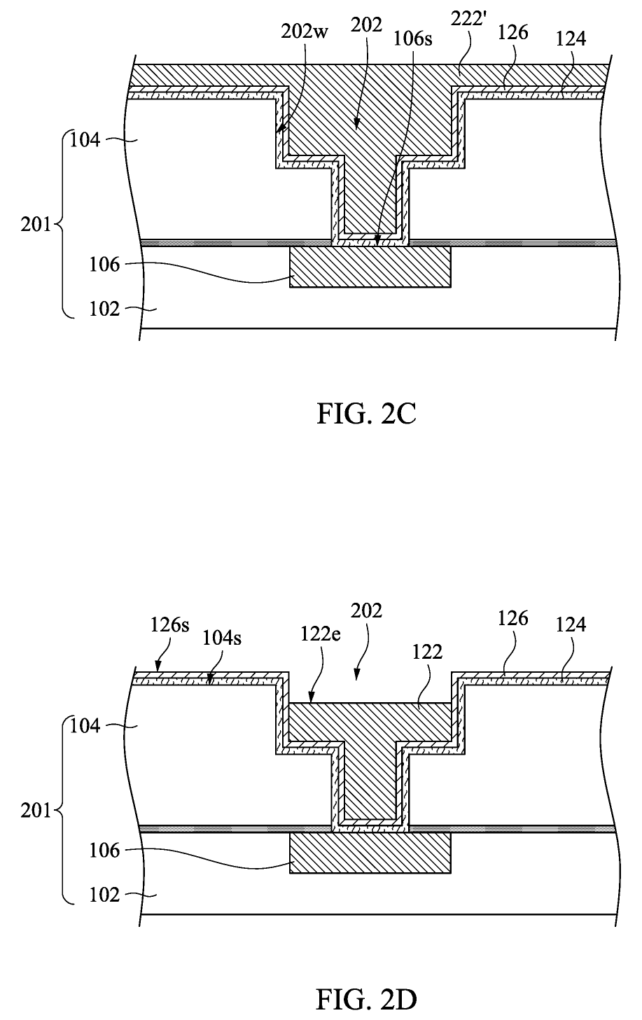

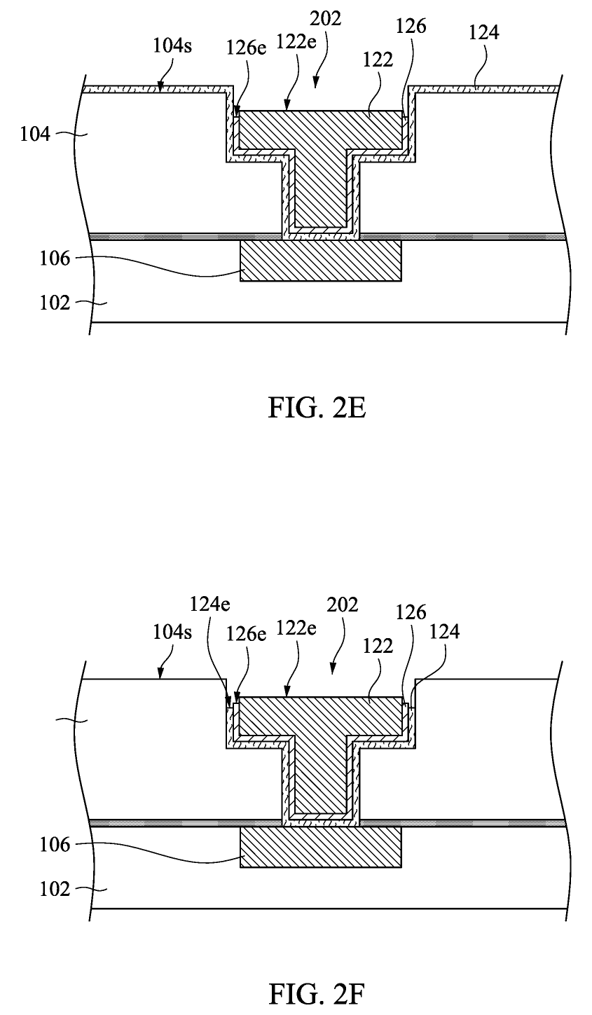

The method for fabrication of a circuit board, which takes the circuit board 100 of FIG. 1A as an example, includes sequent steps illustrated in FIG. 2A to FIG. 2F. Referring to FIG. 2A, firstly, a substrate 201 is provided in this embodiment. The substrate 201 may be formed from a general copper clad laminate (CCL) by lithography, etching and thermal lamination.

The substrate 201 includes the insulation layer 102, the circuit layer 106 embedded in the insulation layer 102 and the insulation layer 104 disposed on the insulation layer 102. The insulation layer 104 includes the flat surface 104s, while the flat surface 104s and the circuit layer 106 are located at two opposite sides of the insulation layer 104. Next, a part of the insulation layer 104 is removed to form at least one opening 202 on the insulation layer 104 by the methods, such as lithography and dry etching (e.g., plasma etching). Since the substrate 201 further includes the etch stop layer 140 between the circuit layer 106 and the insulation layer 104, the etching to the insulation layer 104 is stopped at the interface 106i between the circuit layer 106 and the insulation layer 104, so that the opening 202 exposes the surface 106s of the circuit layer 106.

Referring to FIG. 2B, the diffusion barrier layer 124 is disposed on the insulation layer 104 and an inner wall 202w of the opening 202 by physical vapor deposition (PVD), chemical vapor deposition (CVD) or atomic layer deposition. The diffusion barrier layer 124 covers the surface 106s of the circuit layer 106, specifically, the diffusion barrier layer 124 covers the flat surface 104s of the insulation layer 104, the inner wall 202w of the opening 202 and the surface 106s of the circuit layer 106.

Next, referring to FIG. 2C, a metal material 222’ is disposed on the diffusion barrier layer 124. The metal material 222’ is located inside the opening 202 and may cover the inner wall 202w of the opening 202 and the flat surface 104s of the insulation layer 104. Specifically, the method of disposing the metal material 222’ may include disposing a seed layer (not shown), whose thickness is between 10 nm and 300 nm, on the diffusion barrier layer 124 by PVD, CVD or atomic layer deposition. Next, the metal material 222’ is deposited on this seed layer by deposition methods, such as electroplating.

It is worth mentioning, in order to increase the adhesion between the metal material 222’ and the diffusion barrier layer 124, the method for fabrication of the circuit board 100 further includes disposing the adhesive layer 126 on the diffusion barrier layer 124 before the metal material 222’ is disposed on the diffusion barrier layer 124. The material of the adhesive layer 126 may include titanium, tantalum or similar metals. The adhesive layer 126 is located inside the opening 202 and distributed between the diffusion barrier layer 124 and the metal layer 122, so as to improve the adhesion between the diffusion barrier layer 124 and the metal layer 122.

Next, referring to FIG. 2D, a part of the metal material 222’ (denoted in FIG. 2C) is removed to expose the diffusion barrier layer 124 and the adhesive layer 126 on the flat surface 104s of the insulation layer 104 and to form the metal layer 122 inside the opening 202 by wet etching. It is worth mentioning, since the part of the metal material 222’ is removed by wet etching, the thorough etching should be achieved by over etch. That is, the metal material 222’ which covers the flat surface 104s of the insulation layer 104 is ensured to be removed completely by over etch.

As a result, the metal layer 122 has the end surface 122e which is farther away from the circuit layer 106, while the end surface 122e is recessed to the flat surface 104s of the insulation layer 104. Specifically, the metal material 222’ is over etched by 0.1 µm to 3.0 µm, so that the end surface 122e of the metal layer 122 may be recessed to the surface 126s of the adhesive layer 126. Thus, the distance between the end surface 122e and the surface 126s is between 0.1 µm and 3.0 µm.

Referring to FIG. 2E, a part of the adhesive layer 126 may be removed by wet etching after the metal layer 122 is formed, so that the end surface 126e of the adhesive layer 126 is recessed to the end surface 122e of the metal layer 122, and the diffusion barrier layer 124 on the flat surface 104s of the insulation layer 104 is exposed. In order to ensure the adhesive layer 126 on the flat surface 104s of the insulation layer 104 is completely removed, the adhesive layer 126 is over etched by 10 nm to 200 nm.

Next, referring to FIG. 2F, a part of the diffusion barrier layer 124 may be removed by wet etching after the metal layer 122 is formed (and after the part of the adhesive layer 126 is removed), so that the end surface 124e of the diffusion barrier layer 124 is recessed to the end surface 122e of the metal layer 122, and the flat surface 104s of the insulation layer 104 is exposed. In order to ensure the diffusion barrier layer 124 on the flat surface 104s of the insulation layer 104 is completely removed, the diffusion barrier layer 124 is over etched by 1 nm to 200 nm.

Next, the method for fabrication of the circuit board 100 further includes disposing the etch stop layer 160 (shown in FIG. 1A) on the insulation layer 104 by PVD, CVD or atomic layer deposition after the part of the diffusion barrier layer 124 is removed, while this step is not illustrated in FIG. 2A to FIG. 2F. The etch stop layer 160 covers the end surface 122e of the metal layer 122 and the end surface 124e of the diffusion barrier layer 124.

Next, a circuit substrate (not shown) may be disposed on the etch stop layer 160 by vacuum lamination after the etch stop layer 160 is disposed. This circuit substrate may be such as an Ajinomoto build-up film (ABF), a pregreg or similar materials. Since the insulation layer of the circuit substrate may fill up the recessed region 160t (denoted in FIG. 1A) of the etch stop layer 160 during the process of vacuum lamination, the surface of the circuit board 100 may be flatten.

In conclusion, since at least one embodiment of the disclosure may build up the circuit board by vacuum lamination (e.g., by the vacuum lamination of ABF), the criteria of flatness between the conductive structure embedded in the insulation layer (i.e., the insulation layer 104) and the surface of the insulation layer (i.e., the flat surface 104s of the insulation layer 104) decreases. Therefore, the metal layer of the conductive structure may be formed by deposition (e.g., electroplating) and wet etching as the conducive structure of the circuit board is disposed. Furthermore, the diffusion barrier layer may be formed between the metal layer and the circuit layer by deposition (e.g., by PVD) and wet etching. As a result, the structure whose surface of the conductive structure (i.e., the surface 120s) is recessed to the surface of the insulation layer is formed, and the end surface of the diffusion barrier layer (i.e., the end surface 124e) is recessed to the end surface of the metal layer (i.e., the end surface 122e). The process of CMP is bypassed in the fabrication of this circuit board, thereby reducing the manufacturing cost of the circuit board.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A circuit board, comprising:
a first insulation layer;
a circuit layer embedded in the first insulation layer;
a second insulation layer disposed on the first insulation layer; and
at least one conductive structure embedded in the second insulation layer and having a first surface and a second surface opposite to each other, wherein a flat surface of the second insulation layer exposes the second surface of the at least one conductive structure, and the second surface is recessed to the flat surface of the second insulation layer, wherein the at least one conductive structure comprises:
a metal layer; and
a diffusion barrier layer disposed between the metal layer and the second insulation layer and surrounding an outer surface of the metal layer.

2. The circuit board of claim 1, comprising a plurality of conductive structures, wherein at least one of the conductive structures is disposed on the circuit layer and electrically connected to the circuit layer, and the first surface of the at least one of the conductive structures touches the circuit layer directly.

3. The circuit board of claim 2, wherein the first surface of another one of the conductive structures is spaced from the circuit layer.

4. The circuit board of claim 1, wherein the second surface of the at least one conductive structure comprises a first end surface of the metal layer and a second end surface of the diffusion barrier layer, and the second end surface of the diffusion barrier layer is recessed to the first end surface of the metal layer.

5. The circuit board of claim 4, wherein the at least one conductive structure further comprises:
an adhesive layer distributed between the metal layer and the diffusion barrier layer, wherein the second surface of the at least one conductive structure further comprises a third end surface of the adhesive layer, and the third end surface of the adhesive layer is recessed to the first end surface of the metal layer.

6. The circuit board of claim 5, wherein the second end surface of the diffusion barrier layer is recessed to the third end surface of the adhesive layer.

7. The circuit board of claim 6, wherein a first spacing is located between the second end surface of the diffusion barrier layer and the third end surface of the adhesive layer, and the first spacing is between 1 nm and 100 nm, wherein a second spacing is located between the third end surface of the adhesive layer and the first end surface of the metal layer, and the second spacing is between 10 nm and 200 nm.

8. The circuit board of claim 5, wherein the second end surface of the diffusion barrier layer protrudes from the third end surface of the adhesive layer.

9. The circuit board of claim 1, further comprising:
an etch stop layer disposed between the first insulation layer and the second insulation layer, wherein the etch stop layer covers the circuit layer and exposes an interface of the circuit layer, wherein the at least one conductive structure is disposed on the interface.

10. The circuit board of claim 1, further comprising:
an etch stop layer disposed on the second insulation layer and covering the second surface of the at least one conductive structure.

11. A method for fabricating a circuit board, comprising:
providing a substrate comprising:
a first insulation layer;
a circuit layer embedded in the first insulation layer; and
a second insulation layer disposed on the first insulation layer and comprising a flat surface, wherein the flat surface and the circuit layer are located at two opposite sides of the second insulation layer separately;
removing a part of the second insulation layer to form at least one opening on the second insulation layer, wherein the opening exposes a first surface of the circuit layer;
disposing a diffusion barrier layer on the second insulation layer and an inner wall of the opening, and the diffusion barrier layer covers the first surface of the circuit layer;
disposing a metal material on the diffusion barrier layer, wherein the metal material is located inside the opening; and
removing a part of the metal material to form a metal layer inside the opening, and the metal layer is electrically connected to the circuit layer, wherein the metal layer has a first end surface that is farther away from the circuit layer, and the first end surface is recessed to the flat surface of the second insulation layer.

12. The method of claim 11, further comprising:
removing a part of the diffusion barrier layer after the metal layer is formed, so that a second end surface of the diffusion barrier layer is recessed to the first end surface of the metal layer.

13. The method of claim 12, further comprising:
disposing an etch stop layer on the second insulation layer after the part of the diffusion barrier layer is removed, and the etch stop layer covers the first end surface of the metal layer and the second end surface of the diffusion barrier layer.

14. The method of claim 11, further comprising:
disposing an adhesive layer on the diffusion barrier layer before the metal material is disposed on the diffusion barrier layer, wherein the adhesive layer is located inside the opening and distributed between the diffusion barrier layer and the metal layer; and
removing a part of the adhesive layer after the metal layer is formed, so that a third end surface of the adhesive layer is recessed to the first end surface of the metal layer.

15. The method of claim 11, wherein the method of removing the part of the metal material comprises wet etching.
